(19) United States
(12) Patent Application Publication
(10) Pub. No.: US 2008/0169461 A1
(43) Pub. Date: Jul. 17, 2008

(54) DISPLAY DEVICE AND METHOD OF MANUFACTURING THE SAME

(75) Inventor: Seung-kyu PARK, Hwaseong-si (KR)

Correspondence Address: CANTOR COLBURN, LLP, 20 Church Street, 22nd Floor, Hartford, CT, 06103, US

(73) Assignee: SAMSUNG ELECTRONICS CO., LTD., Suwon-si (KR)

(21) Appl. No.: 11/846,083

(22) Filed: Aug. 28, 2007

(30) Foreign Application Priority Data
Jan. 15, 2007 (KR) 10-2007-0004375

(51) Int. Cl. H01L 35/24; H01L 21/00

(52) U.S. Cl. 257/40; 438/29; 257/E33.001

(57) ABSTRACT

A display device includes; an insulation substrate, a thin film transistor disposed on the insulation substrate and which includes a drain electrode, an insulation layer disposed on the thin film transistor and which includes a contact hole which exposes the drain electrode, a first electrode disposed on the insulation layer and which electrically connects with the drain electrode through the contact hole, a wall disposed on the insulation layer, the wall including an opening and a groove, wherein the opening at least partially exposes the first electrode and the groove at least partially encloses the opening, an organic layer disposed on the first electrode exposed through the opening in the wall; and a second electrode disposed on the organic layer and the wall, at least a portion of the second electrode being disposed on the groove.

This application claims priority to Korean Patent Application No. 10-2007-0004375, filed on Jan. 15, 2007, and all the benefits accruing therefrom under 35 U.S.C. § 119, the contents of which in its entirety are herein incorporated by reference.

### BACKGROUND OF THE INVENTION

a. Field of the Invention

The present invention relates to a display device, and more particularly, to a bottom-emission type display device in which light from an organic layer is emitted via an insulation substrate, and a manufacturing method thereof.

b. Description of the Related Art

Among flat panel display devices, an organic light emitting diode (“OLED”) display device is garnering attention because of its low driving voltage, light weight, thin profile, wide viewing angle and high speed response.

OLED display devices utilize an organic light emitting layer wherein electrons and electron holes (also called simply “holes”) are combined to form excitons. When the excitons de-excite they release energy in the form of visible light. This light may then be used for display purposes.

OLED display devices may be classified into a bottom-emission type and a top-emission type according to an emission direction of light generated from the light emitting layer. In the bottom-emission type of OLED display device, light generated from the light emitting layer is emitted via an insulation substrate disposed below the light emitting layer.

However, in such bottom-emission type OLED display devices light emitting efficiency is reduced due to light diffusion in the insulating substrate, such that the light from one pixel may be spread to appear as light delivered from a neighboring pixel. Also, there color reproducibility may be negatively affected because light is mixed between neighboring pixels.

### BRIEF SUMMARY OF THE INVENTION

Accordingly, it is an aspect of the present invention to provide a display device having an improved light emitting efficiency.

The foregoing and/or other aspects of the present invention are achieved by providing an exemplary embodiment of a display device including; an insulation substrate, a thin film transistor disposed on the insulation substrate and which includes a drain electrode, an insulation layer disposed on the thin film transistor and includes a contact hole which exposes the drain electrode, a first electrode disposed on the insulation layer and which electrically connects with the drain electrode through the contact hole, a wall disposed on the insulation layer, the wall including an opening and a groove, wherein the opening at least partially exposes the first electrode and the groove at least partially encloses the opening, an organic layer disposed on the first electrode exposed through the opening in the wall, and a second electrode disposed on the organic layer and the wall, at least a portion of the second electrode being disposed on the groove.

According to an exemplary embodiment of the present invention, the first electrode comprises a transparent conductive material and the second electrode comprises a reflective material.

According to an exemplary embodiment of the present invention, the display device further comprises a color filter disposed between the insulation substrate and the first electrode, and the organic layer emits white light.

According to an exemplary embodiment of the present invention, the insulation layer comprises a planarization layer made of an organic material, and the color filter is located between the planarization layer and the insulation substrate.

According to an exemplary embodiment of the present invention, the groove extends to the planarization layer, and a distance between a lower end of the groove and the insulation substrate is equal to or smaller than a distance between a lower end of the color filter and the insulation substrate.

According to an exemplary embodiment of the present invention, the insulation layer further includes an inorganic insulation layer located between the planarization layer and the insulation substrate, and the color filter is located between the inorganic insulation layer and the planarization layer.

According to an exemplary embodiment of the present invention, the groove extends to the planarization layer, and the second electrode, which is located on the groove, contacts the inorganic insulation layer.

According to an exemplary embodiment of the present invention, the groove extends to the planarization layer, and a distance between a lower end of the groove and the insulation substrate is equal to or smaller than a distance between a lower end of the color filter and the insulation substrate.

According to an exemplary embodiment of the present invention, the groove at least partially encloses the first electrode in a substantially closed loop.

According to an exemplary embodiment of the present invention, the groove only partially encloses the first electrode.

According to an exemplary embodiment of the present invention, the display device further includes a signal wiring which is disposed on the insulation substrate, wherein the groove does not cross over the signal wiring.

According to an exemplary embodiment of the present invention, the organic layer is separated from the groove.

According to an exemplary embodiment of the present invention, the organic layer extends to substantially cover the wall.

The foregoing and/or other aspects of the present invention are achieved by providing an exemplary embodiment of a display device including; an insulation substrate, a thin film transistor disposed on the insulation substrate and which includes a drain electrode, an insulation layer disposed on the thin film transistor and which includes a contact hole which exposes the drain electrode, a first electrode disposed on the insulation layer and which electrically connects with the drain electrode through the contact hole, a wall disposed on the insulation layer, the wall including an opening and a groove, wherein the opening exposes the first electrode and the groove at least partially encloses the first electrode, an organic layer disposed on at least a portion of the first electrode exposed through the opening in the wall, a second electrode disposed on the organic layer and the wall, at least a part of the second electrode being disposed on the groove, and a color filter disposed between the insulation substrate and the first electrode.

The foregoing and/or other aspects of the present invention are achieved by providing an exemplary embodiment of a display device including; an insulation substrate, a first electrode, an organic layer and a second electrode, sequentially formed on the insulation substrate, the organic layer including a light emitting layer which emits white light, a color filter located between the insulation substrate and the first electrode, and a light reflective layer enclosing a pixel area where the first electrode and the organic layer contact, wherein the light reflective layer is disposed at an oblique angle with respect to the first electrode and extends in a direction substantially towards the insulation substrate, thereby preventing light mixing between adjacent pixel areas.

According to an exemplary embodiment of the present invention, the display device further comprises an inorganic insulation layer disposed on the insulation substrate, wherein the color filter is located between the inorganic insulation layer and the first electrode, and the light reflective layer contacts the inorganic insulation film.

According to an exemplary embodiment of the present invention, the light reflective layer and the second electrode are integrated in one body.

According to an exemplary embodiment of the present invention, a distance between a lower end of the light reflective layer and the insulation substrate is equal to or smaller than a distance between a lower end of the color filter and the insulation substrate.

According to an exemplary embodiment of the present invention, the light reflective layer at least partially encloses the pixel area in a substantially closed loop.

According to an exemplary embodiment of the present invention, the light reflective layer only partially encloses the pixel area.

According to an exemplary embodiment of the present invention, the display device further comprises a signal wiring disposed on the insulation substrate, wherein the groove does not cross over the signal wiring.

According to an exemplary embodiment of the present invention, the organic layer is separated from the light reflective layer in a region where the light reflective layer extends in a direction oblique to the first electrode.

Another exemplary embodiment of the present invention provides a method of manufacturing a display device, the method including; disposing a thin film transistor on an insulation substrate, the thin film transistor including a drain electrode, disposing an insulation layer on the thin film transistor, the insulation layer including a contact hole which exposes the drain electrode, disposing a first electrode on the insulation layer, the first electrode electrically connecting with the drain electrode through the contact hole, disposing a wall on the insulation layer, the wall including an opening and a groove, wherein the opening at least partially exposes the first electrode and the groove at least partially surrounds the opening, disposing an organic layer on the first electrode which is exposed through the opening in the wall, and disposing a second electrode on the organic layer and the wall, at least a portion of the second electrode being disposed on the groove.

### BRIEF DESCRIPTION OF THE DRAWINGS

The above and/or other aspects of the present invention will become apparent and more readily appreciated from the following description of the exemplary embodiments, taken in conjunction with the accompanying drawings in which:

FIG. 1 is an equivalent circuit diagram of a first exemplary embodiment of a display device according to the present invention;

FIGS. 2 and 3 are top plan view layouts of the first exemplary embodiment of a display device according to the present invention;

FIG. 4 is a cross-sectional view taken along line IV-IV of FIG. 2;

FIG. 5 is a cross-sectional view taken along line V-V of FIG. 3;

FIGS. 6A through 14B are cross-sectional views illustrating an exemplary embodiment of a method of manufacturing a first exemplary embodiment of a display device according to the present invention;

FIG. 15 is a cross-sectional view of a second exemplary embodiment of a display device according to the present invention;

FIG. 16 is a cross-sectional view of a third exemplary embodiment of a display device according to the present invention;

FIG. 17 is a top plan view layout of a fourth exemplary embodiment of a display device according to the present invention;

FIG. 18 is a top plan view layout of a fifth exemplary embodiment of a display device according to the present invention; and

FIG. 19 is a top plan view layout of a sixth exemplary embodiment of a display device according to the present invention.

### DETAILED DESCRIPTION OF THE INVENTION

The invention now will be described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on” another element, it can be directly on the other element or intervening elements may be present therebetween.

In contrast, when an element is referred to as being “directly on” another element, there are no intervening elements present. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another element, component, region, layer or section.

Thus, a first element, component, region, layer or section discussed below could be termed a second element, component, region, layer or section without departing from the teachings of the present invention.

The terminology used herein is for the purpose of describing particular embodiments only and is not intended to be limiting of the invention. As used herein, the singular forms “aa”, “an” and “the” are intended to include the plural forms as well, unless the context clearly indicates otherwise. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another elements as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower”, can therefore, encompasses both an orientation of “lower” and “upper,” depending of the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Exemplary embodiments of the present invention are described herein with reference to cross section illustrations that are schematic illustrations of idealized embodiments of the present invention. As such, variations from the shapes of the illustrations as a result, for example, of manufacturing techniques and/or tolerances, are to be expected. Thus, embodiments of the present invention should not be construed as limited to the particular shapes of regions illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present invention.

Hereinafter, the present invention will be described in detail with reference to the accompanying drawings.

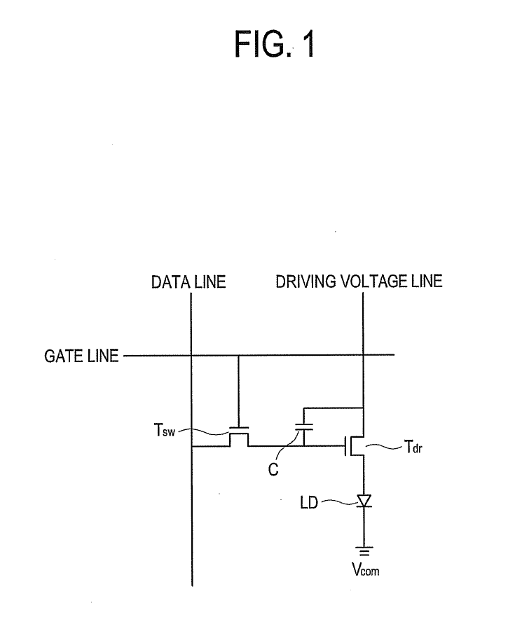

FIG. 1 is an equivalent circuit diagram of a pixel in a first exemplary embodiment of a display device according to the present invention.

A number of signal lines are provided in a single pixel. The signal lines include a gate line, which transfers a scanning signal, a data line, which transfers a data signal, and a driving voltage line, which transfers a driving voltage. In the current exemplary embodiment the data line and the driving voltage line are arranged substantially in parallel, and the gate line is extended substantially perpendicularly to the data line and the driving voltage line. Alternative exemplary embodiments include configurations wherein the gate line, data line and driving voltage line are arranged differently.

Each pixel includes an organic light emitting component LD, a switching thin film transistor Tsw, a driving thin film transistor Tdr, and a capacitor C. In one exemplary embodiment the organic light emitting component is an organic light emitting diode (“OLED”).

The driving thin film transistor Tdr has a control terminal, an input terminal and an output terminal, in which the control terminal is connected to the switching thin film transistor Tsw, the input end is connected to the driving voltage line, and the output end is connected to the organic light emitting component LD.

The organic light emitting component LD has an anode connected to the output terminal of the driving thin film transistor Tdr and a cathode to which a common voltage is applied. The light emitting component LD emits light of various intensity according to the output current of the driving thin film transistor Tdr. Images can be displayed by combining the light emitted from a plurality of light emitting components contained in a plurality of pixels of the display. The electric current transmitted by the driving thin film transistor Tdr varies according to the voltage applied between the control terminal and the output terminal thereof.

Moving images may be created by rapidly displaying a series of images in sequence. Each image in the series is called a frame.

The switching thin film transistor Tsw also has a control terminal, an input terminal, and an output terminal, in which the control terminal is connected to the gate line, the input terminal is connected to the data line, and the output terminal is connected to the control terminal of the driving thin film transistor Tdr. The switching thin film transistor Tsw transfers a data signal, which is applied to the data line to the driving thin film transistor Tdr, according to a scanning signal which is applied to the gate line.

The capacitor C is connected between the control terminal and the input terminal of the driving thin film transistor Tdr. The capacitor C charges the data signal input to the control terminal of the driving thin film transistor Tdr and maintains the charge for substantially an entire frame.

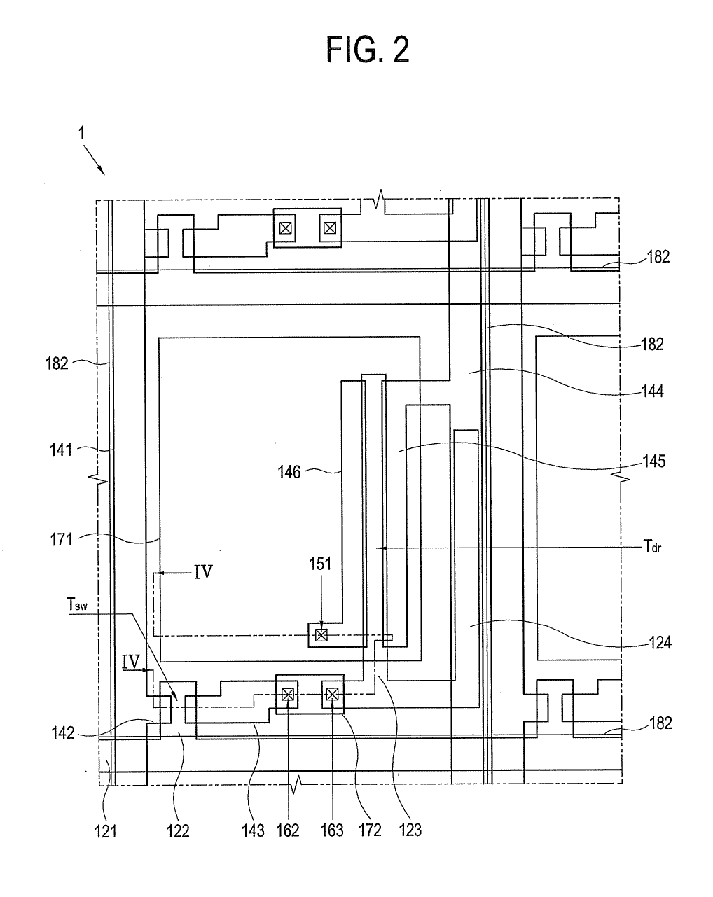

The first exemplary embodiment of a display device according to the present invention will be described below in detail with reference to FIGS. 2 through 5.

Gate wiring is formed on an insulation substrate 110. The gate wiring includes: a gate line 121 which is arranged in parallel with other gate lines, the gate lines being separated by a certain interval; a switching gate electrode 122 formed as part of a switching transistor Tsw; a driving gate electrode 123 formed as a part of a driving transistor Tdr; and a storage electrode 124 which extends below a driving voltage line 144 thereby forming a capacitor.

Here, the gate line 121 and the switching gate electrode 122 are integrally formed as one body, and the driving gate electrode 123 and the storage electrode 124 are also integrally as one body. However, alternative exemplary embodiments include configurations wherein the gate line 121 and the switching gate electrode 122, and/or the driving gate electrode 123 and the storage electrode 124, may be formed separately and later connected, e.g., by a bridging member.

A first inorganic insulation layer 130 is formed on the gate wiring. The first inorganic insulation layer 130 is made of an inorganic material, exemplary embodiments of which include silicon nitride.

A switching semiconductor layer 131 is formed on a portion of the first inorganic insulation layer 130 located on the switching gate electrode 122, and a driving semiconductor layer 133 is formed on the first inorganic insulation layer 130 located on the driving gate electrode 123.

In one exemplary embodiment the semiconductor layers 131 and 133 are made of amorphous silicon, fine crystalline silicon, poly-silicon, or other similar materials. Ohmic contact layers 132 and 134 are located on the semiconductor layers 131 and 133, respectively. The ohmic contact layers 132 and 134 include a switching ohmic contact layer 132 formed on the switching semiconductor layer 131 and a driving ohmic contact layer 134 formed on the driving semiconductor layer 133.

Each ohmic contact layer 132 or 134 is separated into two parts around gate electrodes 122 and 123, respectively. In one exemplary embodiment the ohmic contact layers 132 and 134 may be formed of n+ silicon or other similar materials. In the exemplary embodiment wherein the semiconductor layers 131 and 133 are made of poly-silicon, the ohmic contact layers 132 and 134 may also be made of poly-silicon.

Data wiring is formed on the ohmic contact layers 132 and 134 and the first inorganic insulation layer 130. The data wiring includes: a data line 141 which extends substantially perpendicular to the gate line 121; a switching source electrode 142 and a switching drain electrode 143 which form part of the switching thin film transistor Tsw; a driving voltage line 144 applying a driving voltage; and a driving source electrode 145 and a driving drain electrode 146 which form part of the driving thin film transistor Tdr.

In the present exemplary embodiment the data line 141 and the switching source electrode 142 are integrally formed as one body, and the driving voltage line 144 and the driving source electrode 145 are also integrally formed as one body.

A second inorganic insulation layer 150 is formed on the data wiring and the semiconductor layers 131 and 133 which are not covered by the data wiring. Exemplary embodiments of the second inorganic insulation layer 150 can be made of silicon nitride, silicon oxide, or other similar materials.

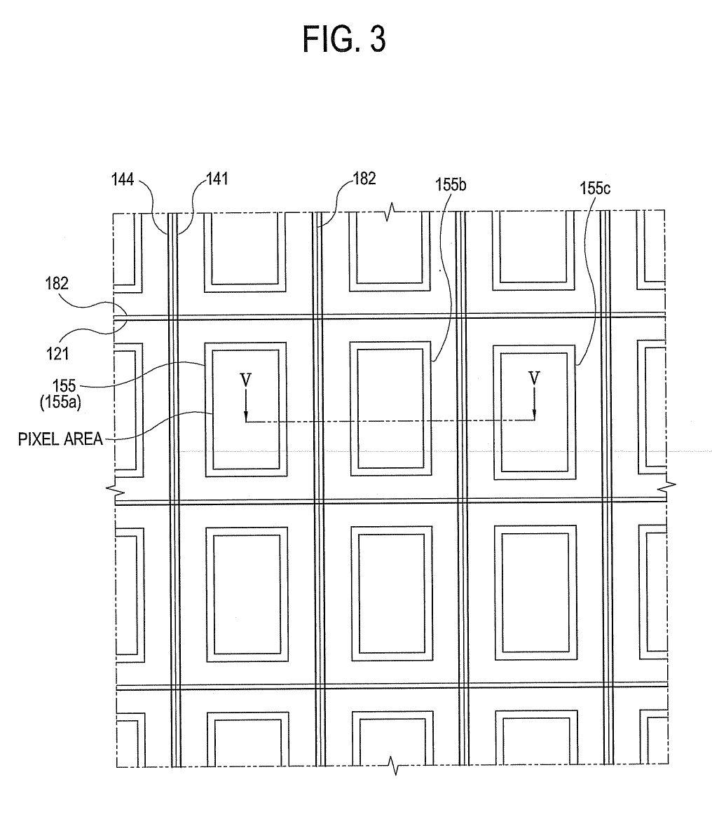

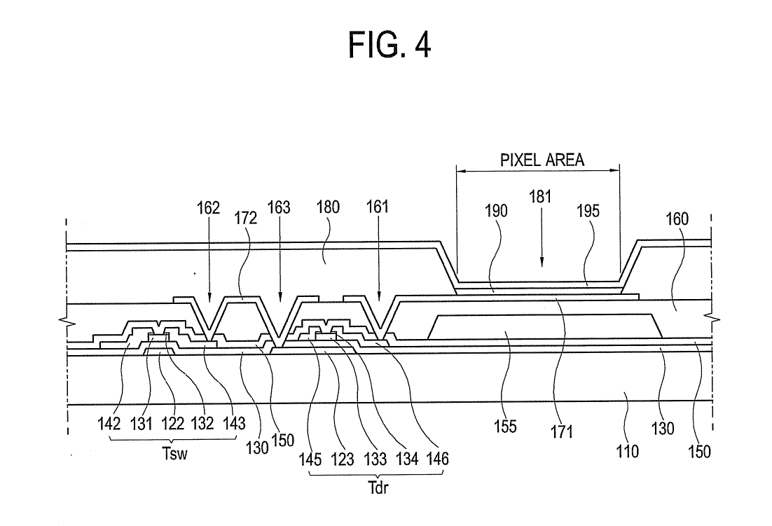

A color filter 155 is formed on the second inorganic insulation layer 150. As illustrated in FIGS. 3 and 4, the color filter 155 is formed as an island, and the color filter 155 may include a red colored sub-color filter 155a, a green sub-colored filter 155b or a blue colored sub-color filter 155c. The color filter 155 can be made of a photoresist material. A planarization layer 160 is formed on the second inorganic insulation layer 150 and the color filter 155. The planarization layer 160 functions as an additional insulation layer. In one exemplary embodiment the planarization layer 160 can be made of an organic material. Exemplary embodiments of an organic material used in the planarization layer include materials from the benzocyclobutene (“BCB”) series, olefin series, acrylic resin series, polyimide series, a fluoropolymer, or other similar materials.

A contact hole 161 which exposes a driving drain electrode 146, a contact hole 162 which exposes a switching drain electrode 143 and a contact hole 163 which exposes a driving gate electrode 123 are formed in the planarization layer 160. The second inorganic insulation layer 150 is removed from the contact holes 161 and 162, and the first inorganic insulation layer 130 and the second inorganic insulation layer 150 are removed from the contact hole 163.

That is, all the insulation layers 130, 150 and 160 have been removed from the contact hole 163.

A transparent conductive layer is formed on the planarization layer 160. The transparent conductive layer includes a pixel electrode 171 and a bridge electrode 172, and exemplary embodiments thereof may be made of indium tin oxide (“ITO”) or indium zinc oxide (“IZO”).

The pixel electrode 171 is electrically connected with the driving drain electrode 146 through the contact hole 161. The bridge electrode 172 electrically connects the switching drain electrode 143 and the driving gate electrode 123 through the contact holes 162 and 163.

A wall 180 is formed on the planarization layer 160. The wall 180 partitions the pixel electrodes 171 of adjacent pixels from one another. An opening 181, which exposes the pixel electrode 171, is formed in the wall 180.

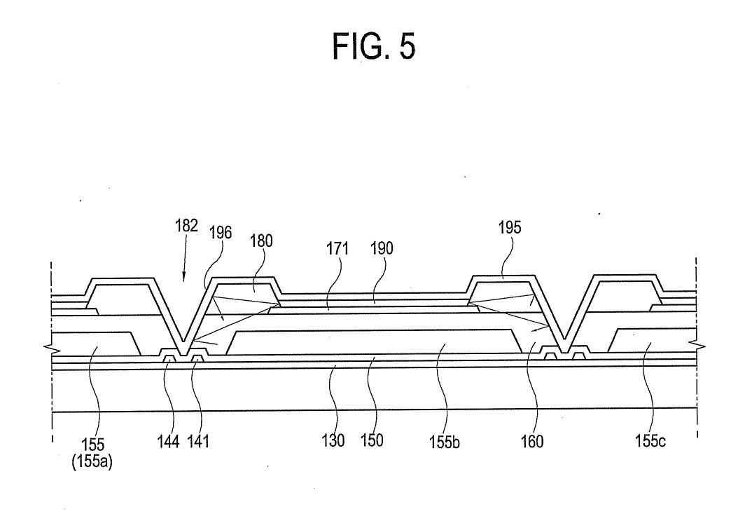

Referring to FIGS. 3 and 5, a groove 182 having a lattice shape is formed in the wall 180. In addition to removing the wall 180 material, the planarization layer 160 is also removed along the groove 182. Accordingly, the groove 182 exposes the second inorganic insulation layer 150.

An organic layer 190 is formed on the region of the pixel electrode 171 exposed by the opening 181. The organic layer 190 includes an organic light emitting layer and exemplary embodiments thereof may be made of a polymer material or a low-molecular weight material.

In the exemplary embodiment wherein the organic layer 190 is made of a low-molecular weight material, the organic layer 190 may include an electron injection layer, an electron transport layer, a hole injection layer, a hole transport layer, or any combination thereof in addition to the organic light emitting layer. The additional layers may be used to improve the light emitting efficiency of the organic light emitting diode (“OLED”) of the OLED display.

Exemplary embodiments of the hole injection layer and the hole transport layer include an amine derivative having strong fluorescence a styrilamine derivative, and an aromatic condensation ring. Exemplary embodiments of an amine derivative having strong fluorescence includes an amine derivative having a triphenyldiamine derivative.

An exemplary embodiment of the electron transport layer may include a quinoline derivative, exemplary embodiments of which include aluminum tris (8-hydroxyquinoline) “Alq3”. Alternative exemplary embodiments of the electron transport layer may include a phenyl anthracene derivative or a tetraarylethen derivative. Exemplary embodiments of the electron injection layer can be formed of Ba, Ca or other similar materials.

In the current exemplary embodiment the organic light emitting layer emits white light. In one exemplary embodiment a red color light emitting material layer, a blue color light emitting material layer, and a green light emitting material layer can be laminated to form the organic light emitting layer. Alternative exemplary embodiments include configurations wherein a white light emitting material layer only is used. Alternative exemplary embodiments also include configurations wherein a single color light emitting material layer, e.g., red, blue or green, is used; such an exemplary embodiment eliminates the need for an additional color filter layer 155.

In the exemplary embodiment wherein the organic layer 190 is made of a low-molecular weight material, the organic layer 190 can be formed using a heat evaporation method. In the current exemplary embodiment the organic layer 190 is mainly formed on the pixel electrode 171 with little to know extension up the sides of the wall 180. This is because the organic layer 190 is formed using a shadow mask in the heat evaporation method.

In the exemplary embodiment wherein the organic layer 190 is made of a polymer material, the organic layer 190 may include an organic light emitting layer and an electron injection layer, and may be formed by an ink jetting method.

An area where the pixel electrode 171 and the organic layer 190 contact directly is called a pixel area. In the present exemplary embodiment the pixel area nearly conforms to the area of the opening 181 in the exemplary embodiment.

Referring to FIG. 3, the pixel area is disposed above the area of the color filter 155, and the color filter 155 is surrounded by the groove 182.

A common electrode 195 is formed on the wall 180 and the organic layer 190. In the present exemplary embodiment the common electrode 195 includes a reflective metal layer. The light emitted towards the common electrode 195 from the organic layer 190 is reflected therefrom. The light reflected from the common electrode 195 is directed towards the insulation substrate 110.

The common electrode 195 extends into the groove 182, and the portion of the common electrode 195 which extends into the groove 182 forms a light reflective layer 196.

The light reflective layer 196 contacts the second inorganic insulation layer 150 through the groove 182. Because the color filter 155 is formed on the second inorganic insulation layer 150, the lower end of the color filter 155 and the lower end of the light reflective layer 196 may be located at substantially the same distance from the insulation substrate 110.

In another exemplary embodiment, thicknesses of the inorganic insulation layers 130 and 150 can decrease during forming the groove 182. In such an exemplary embodiment, the lower end of the light reflective layer 196 may be disposed closer to the insulation substrate 110 than the lower end of the color filter 155.

A flow of light generated from the organic layer 190 will be described below.

Holes delivered from the pixel electrode 171 and electrons delivered from the common electrode 195 are combined in the organic layer 190 to form an exciton. Light is generated when the exciton de-excites. The light is generated in a non-directional manner, such that individual photons may be emitted substantially perpendicular to the insulation substrate 110 or at substantially any angle with respect thereto. The light which is emitted towards the common electrode 195 is reflected therefrom. The light reflected from the common electrode 195 is directed towards the pixel electrode 171.

The pixel electrode 171 and the insulation substrate 110 are substantially transparent, and therefore light generated from the organic layer 190 passes through the pixel electrode 171 and the insulation substrate 110 and is emitted to the outside.

The light which is emitted at an angle so that it does not pass directly through the insulation substrate 110 is reflected from the light reflective layer 196 and does not enter neighboring pixel areas. That is, because of the reflective layer 196 light which would normally travel in a direction substantially parallel to the insulation substrate 110 to be emitted from a neighboring pixel area, is instead reflected to be emitted from the pixel area in which it was originally emitted. Therefore, light interference between pixel areas is substantially reduced or effectively prevented. Therefore, a color reproducibility of the display device 1 is improved.

In the exemplary embodiment wherein the color filter 155 and the planarization layer 160 are applied, a substantially percentage of light generated from the organic layer 190 is directed obliquely through the color filter 155, the planarization layer 160 and/or the wall 180. When the reflective layer 196 is not applied, the light is scattered in the color filter 155, the planarization layer 160 and the wall 180 and is possibly passed to be transmitted through adjacent pixels of the display. The scattering of the light lowers the brightness of light and deteriorates light emitting efficiency. Furthermore, the transmission of light generated by one pixel to another pixel deteriorates overall display quality. According to the first exemplary embodiment, travel of the light emitted by the organic layer 190 is limited by the light reflective layer 196, and thus a scattering of the light decreases. Accordingly, brightness of the emitted light increases to thereby improve the light emitting efficiency of the display.

Meanwhile, light may be absorbed while passing through the color filter 155, the planarization layer 160 and the wall 180. The light reflective layer 196 shortens the distance light must travel through absorptive mediums before being emitted to an outside, and therefore total light absorption is decreased.

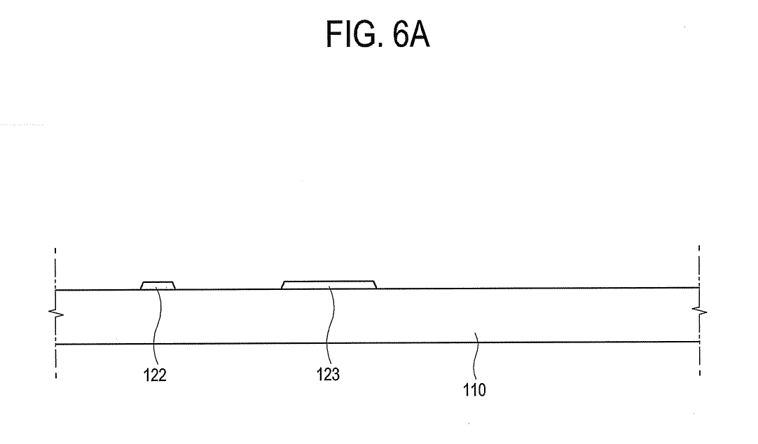

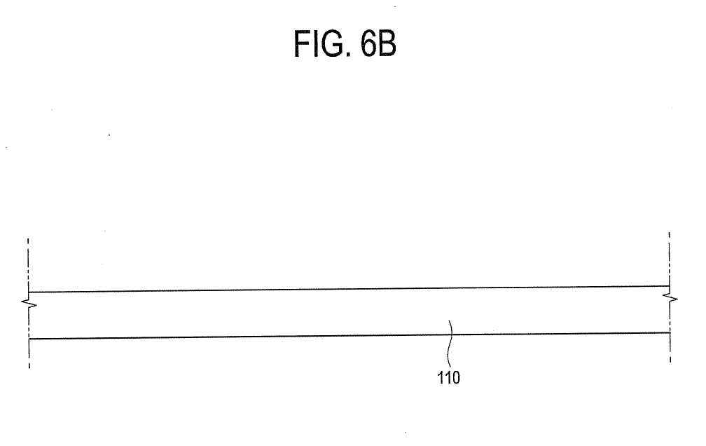

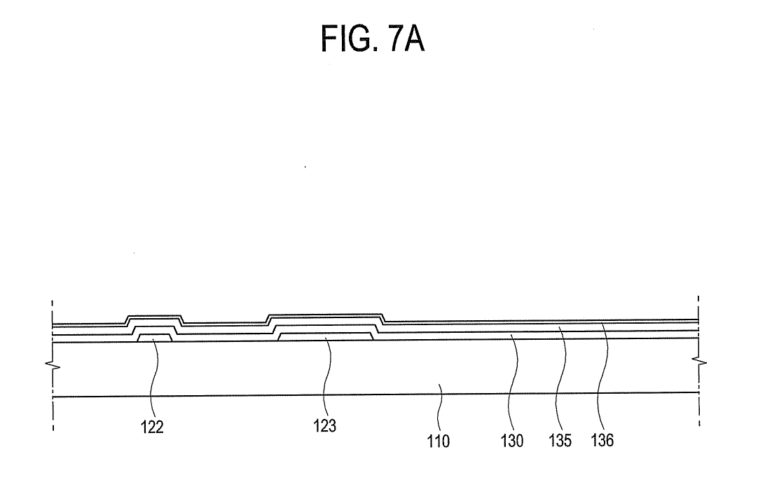

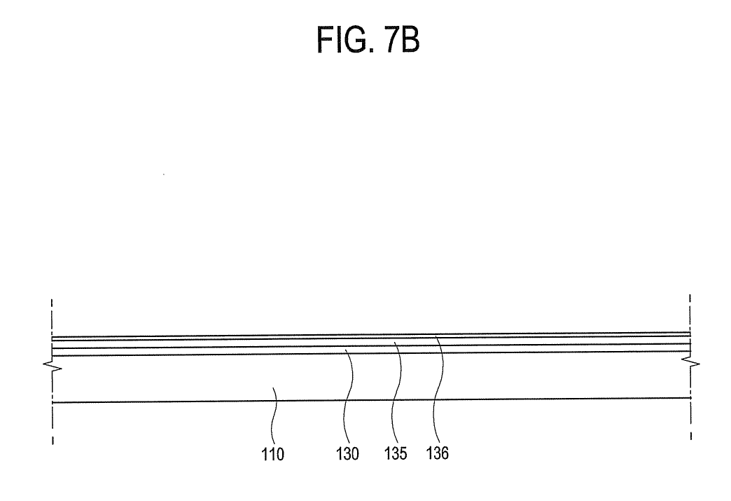

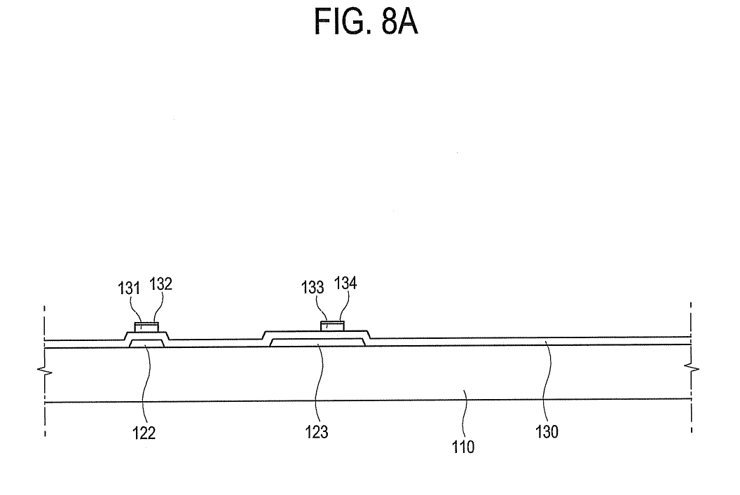

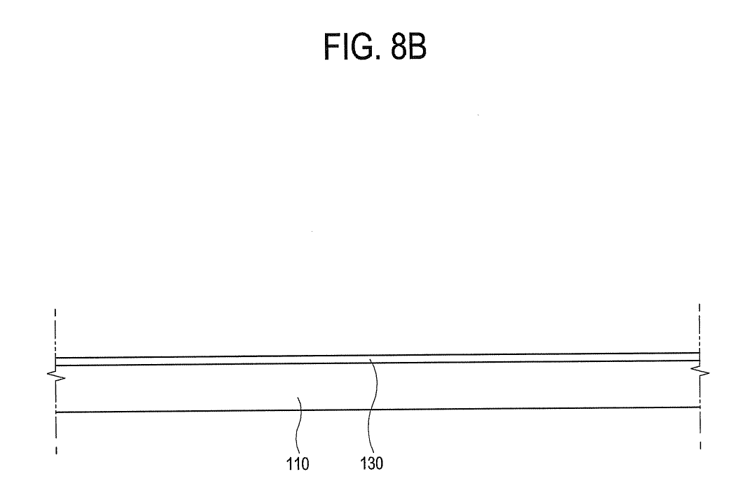

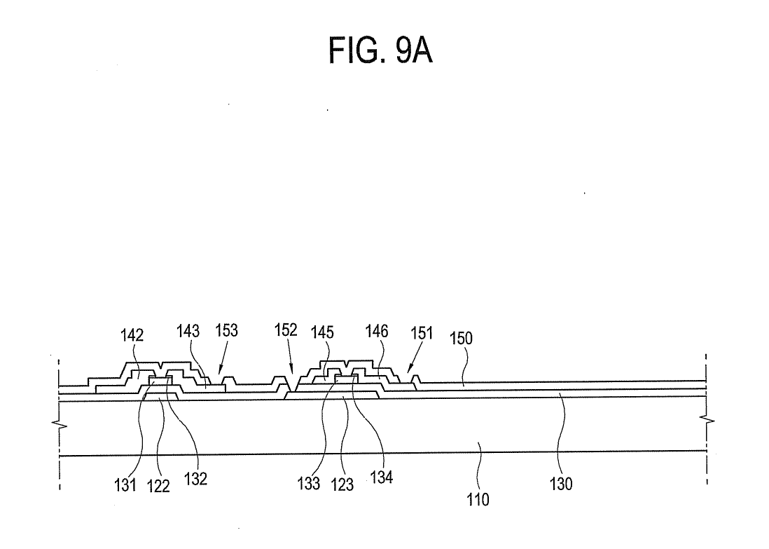

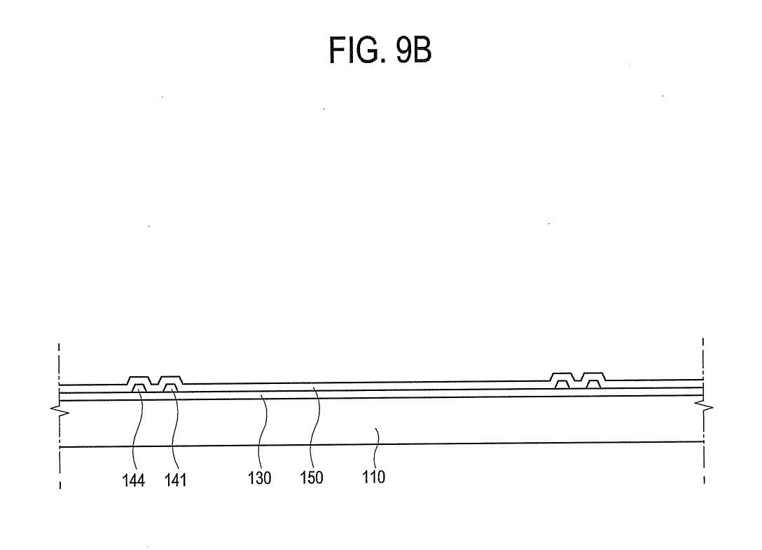

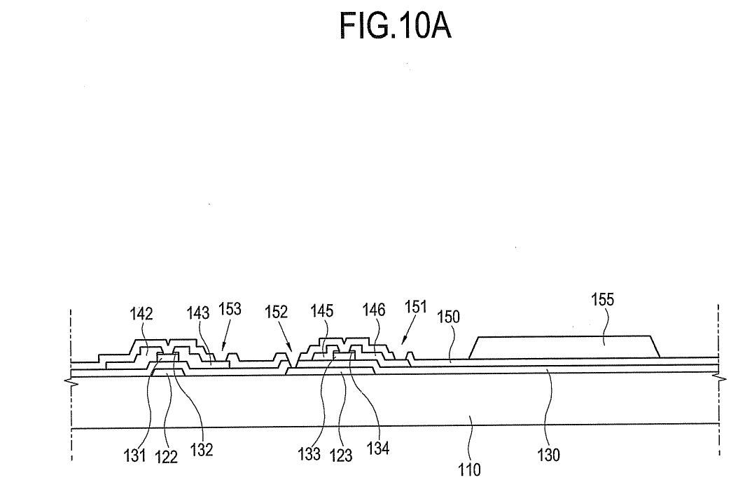

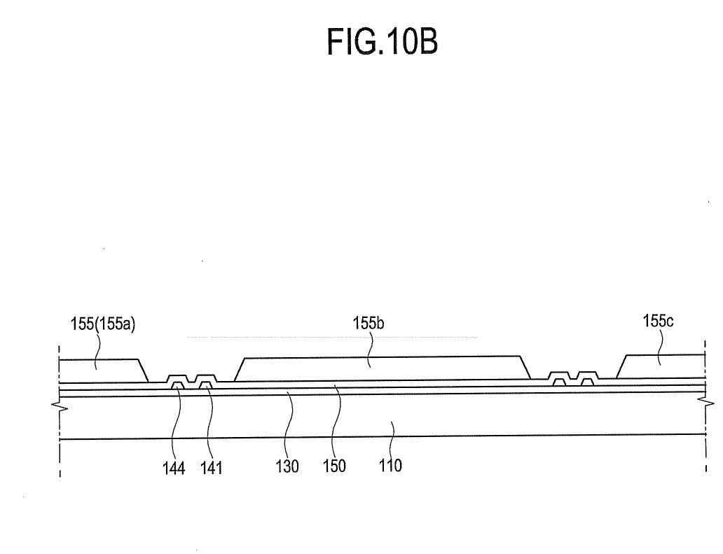

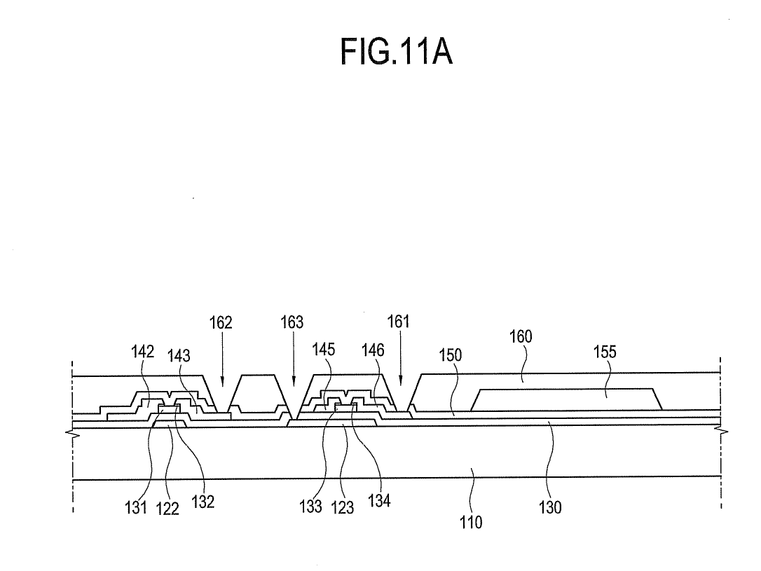

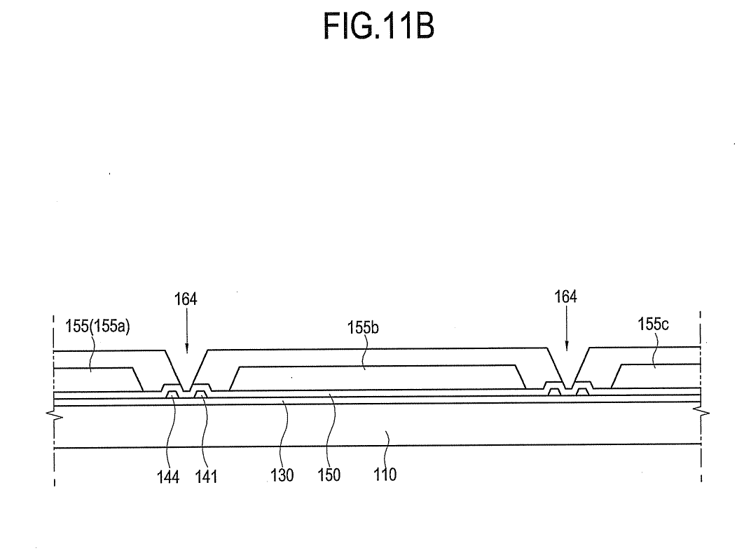

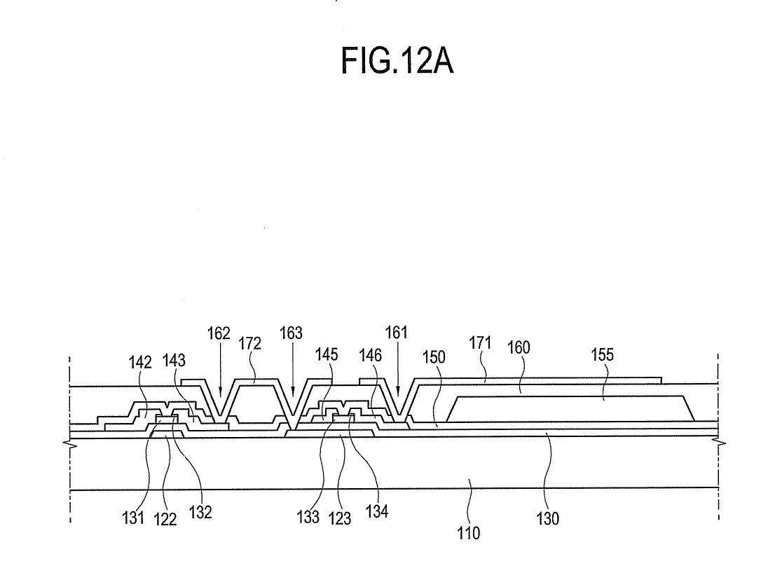

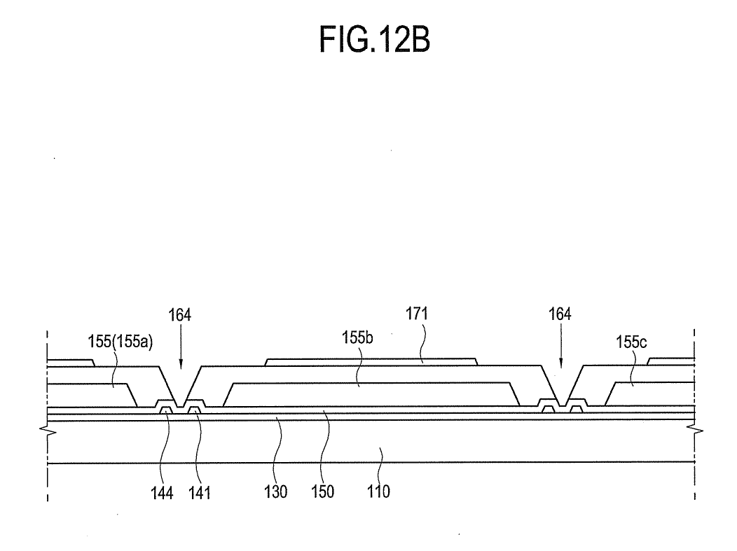

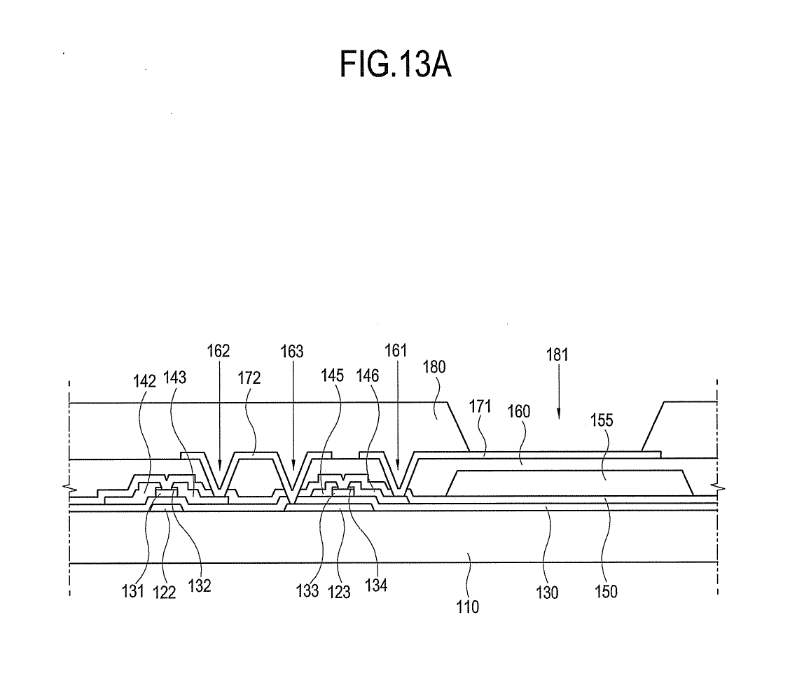

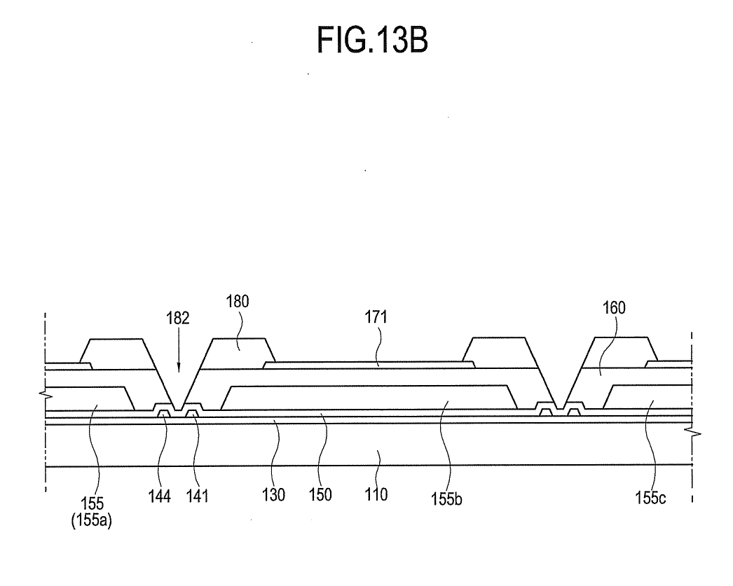

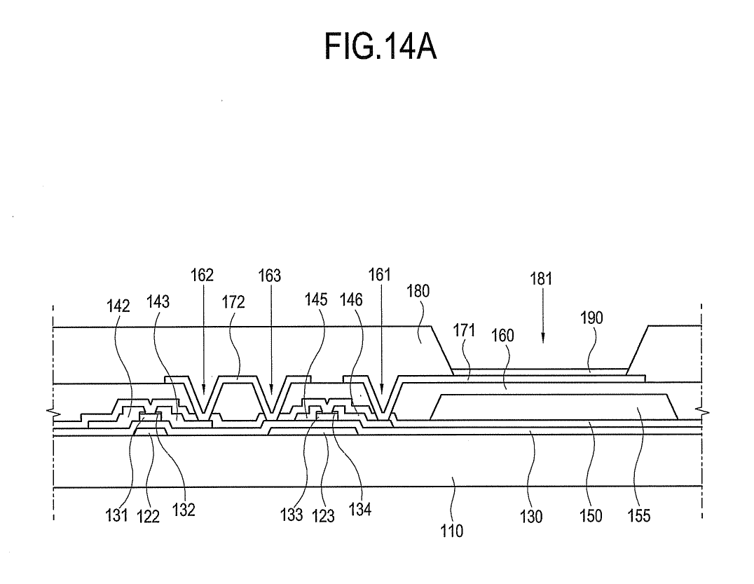

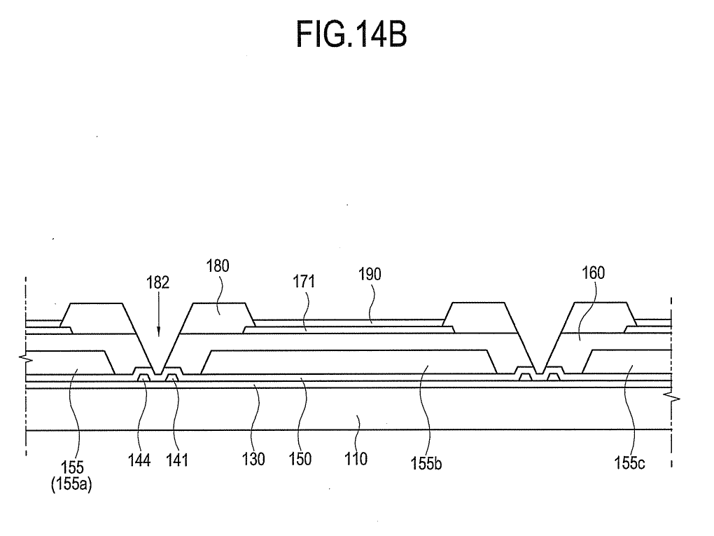

An exemplary embodiment of a method of manufacturing a first exemplary embodiment of a display device according to the present invention will be described below with reference to FIGS. 6A through 14B. FIG. 6A, FIG. 7A, FIG. 8A, FIG. 9A, FIG. 10A, FIG. 11A, FIG. 12A, FIG. 13A, and FIG. 14A illustrate an exemplary embodiment of a method of manufacturing the first exemplary embodiment of a display device taken along line IV-IV of FIG. 2, and FIG. 6B, FIG. 7B, FIG. 8B, FIG. 9B, FIG. 10B, FIG. 11B, FIG. 12B, FIG. 13B, and FIG. 14B illustrate an exemplary embodiment of a method of manufacturing the first exemplary embodiment of a display device taken along line V-V of FIG. 3.

First, as illustrated in FIGS. 6A and 6B, a metal layer is formed on the insulation substrate 110 and patterned to thereby form gate electrodes 122 and 123.

Then, as shown in FIGS. 7A and 7B, a first inorganic insulation layer 130, an amorphous silicon layer 135 and an n+ amorphous silicon layer 136 are formed overlaying the patterned gate electrodes 122 and 123 and the insulation substrate 110.

Then, the amorphous silicon layer 135 and the n+ amorphous silicon layer 136 are crystallized. Exemplary embodiments of the crystallization method include a solid-phase crystallization method, a laser crystallization method, a rapid heat treatment method, and various other similar crystallization methods.

In the exemplary embodiment wherein solid-phase crystallization is used, the amorphous silicon layer 135 is thermally treated for long hours at a temperature lower than or equal to about 60° C., to obtain poly-silicon having relatively large crystal grains. The exemplary embodiment utilizing the laser crystallization method forms poly-silicon from the amorphous silicon layer 135 by using a laser; exemplary embodiments of the laser crystallization method includes an excimer laser annealing method, a sequential lateral solidification method, and various other laser crystallization methods. In the exemplary embodiment utilizing the rapid heat treatment method, the amorphous silicon layer 135 is deposited at low temperature and then rapidly heated by light, to thereby achieve crystallization.

Then, as shown in FIGS. 8A and 8B, after the amorphous silicon layer 135 and the n+ amorphous silicon layer 136 are crystallized they are then patterned, to thereby form semiconductor layers 131 and 133 and ohmic contact layers 132 and 134 made of poly-silicon. At this stage in the exemplary embodiment of the method of manufacturing a display device according to the first exemplary embodiment, the ohmic contact layers 132 and 134 are not yet separated into two parts.

Then, as shown in FIGS. 9A and 9B, a metal layer is deposited and patterned to form a data line 141, a driving voltage line 144, a switching source electrode 142, a switching drain electrode 143, a driving source electrode 145 and a driving drain electrode 146. After having formed the data line 141, the driving voltage line 144, the switching source electrode 142, the switching drain electrode 143, the driving source electrode 145 and the driving drain electrode 146, the exposed ohmic contact layers 132 and 134 are etched and removed. As a result, the respective ohmic contact layers 132 and 134 are separated into two parts. In this process, some of the semiconductor layers 131 and 133 in the channel region may also be also removed.

A second inorganic insulation layer 150 is formed on the a data line 141, a driving voltage line 144, a switching source electrode 142, a switching drain electrode 143, a driving source electrode 145 and a driving drain electrode 146. Contact holes 151, 152 and 153 are formed on the second inorganic insulation layer 150 through patterning. The first inorganic insulation layer 130 is also removed from the contact hole 152.

Accordingly, a switching transistor Tsw and a driving transistor Tdr are completed.

Then, as shown in FIGS. 10A and 10B, a color filter 155 is formed on the second inorganic insulation layer 150. In one exemplary embodiment the color filter 155 may be formed by forming, exposing and developing a color filter photoresist film. This process may be repeated to separately form each sub-color filter 155a, 155b or 155c.

Then, as shown in FIGS. 11A and 11B, a planarization layer 160 is formed. Contact holes 161, 162 and 163 and a groove 164 are formed in the planarization layer 160. In one exemplary embodiment the planarization layer 160 can be formed by forming, exposing and developing a photoresist film.

As shown in FIG. 11B, the groove 164 exposes the second inorganic insulation layer 150. Some or the whole of the second inorganic insulation layer 150 which is exposed by the groove 164 can be removed during the formation of the groove 164 in the planarization layer 160.

Then, as shown in FIGS. 12A and 12B, a transparent conductive film of ITO, IZO, or other similar materials, is deposited and then photolithographed to thereby form a pixel electrode 171 and a bridge electrode 172.

The pixel electrode 171 is connected with the driving drain electrode 146 through the contact hole 161, and the bridge electrode 172 connects the switching drain electrode 143 and the driving gate electrode 123 through the contact holes 162 and 163.

Then, as shown in FIGS. 13A and 13B, a wall 180 is formed on the planarization layer 160, the pixel electrode 171 and the bridge electrode 172. An opening 181 which exposes the pixel electrode 171 and a groove 182 which exposes the second inorganic insulation layer 150 are formed in the wall 180. In one exemplary embodiment the wall 180 can be formed by forming, exposing and developing a photoresist film. In such an exemplary embodiment the photoresist film can be formed by a slit coating or spin coating method.

Then, as shown in FIGS. 14A and 14B, an organic layer 190 is formed. In one exemplary embodiment the organic layer 190 can be formed of a plurality of layers including an organic light emitting layer. In one exemplary embodiment the organic layer 190 can be formed by a dry method.

One exemplary embodiment of a dry method includes a thermal evaporation method. In the exemplary embodiment wherein the thermal evaporation method is used, the insulation substrate 110 is arranged so that a pixel electrode 171 is directed downwards, and then vapor of an organic material is supplied from below the insulation substrate 110.

The organic layer 190 illustrated in the first exemplary embodiment is formed using a shadow mask having a vapor passing hole (not shown) corresponding to the pixel electrode 171.

Finally, a common electrode 195 is formed and a display device 1 as shown in FIGS. 2 and 3 is completed. Exemplary embodiments of the common electrode 195 can be formed by sputtering or thermal evaporation. In the exemplary embodiment wherein thermal evaporation is used to form the common electrode, an open mask is used so that the common electrode 195 can be formed in the groove 182.

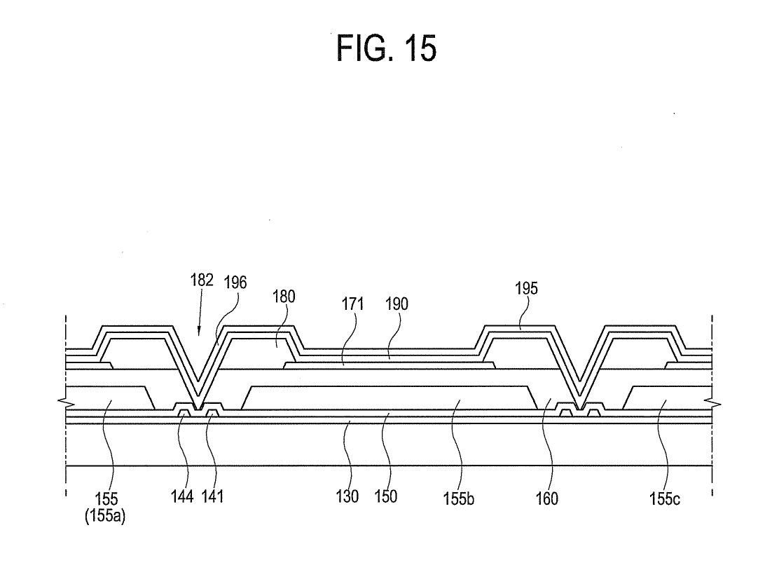

Referring to FIG. 15, a second exemplary embodiment of the present invention will be described below.

An organic layer 190 is formed by a thermal evaporation method using an open mask in the second exemplary embodiment.

Here, the organic layer 190 is formed on a much larger surface area than the first exemplary embodiment, including on a groove 182 and a wall 180.

In other exemplary embodiments, some layers of the organic layer 190 may be formed using an open mask and the other layers of the organic layer 190 may be formed using a shadow mask.

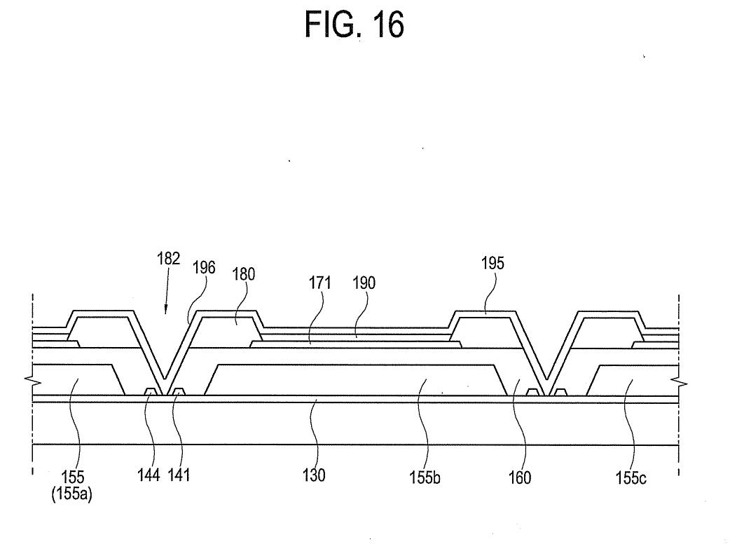

Referring to FIG. 16, a third exemplary embodiment of the present invention will be described below.

In the third exemplary embodiment of the present invention a planarization layer 160 directly contacts a data line 141 and a driving voltage line 144. A color filter 155 and a light reflective layer 196 directly contact a first inorganic insulation layer 130.

In the third exemplary embodiment, a second inorganic insulation layer 150 is not formed, and thus a method of manufacturing the third exemplary embodiment of a display device is correspondingly simplified.

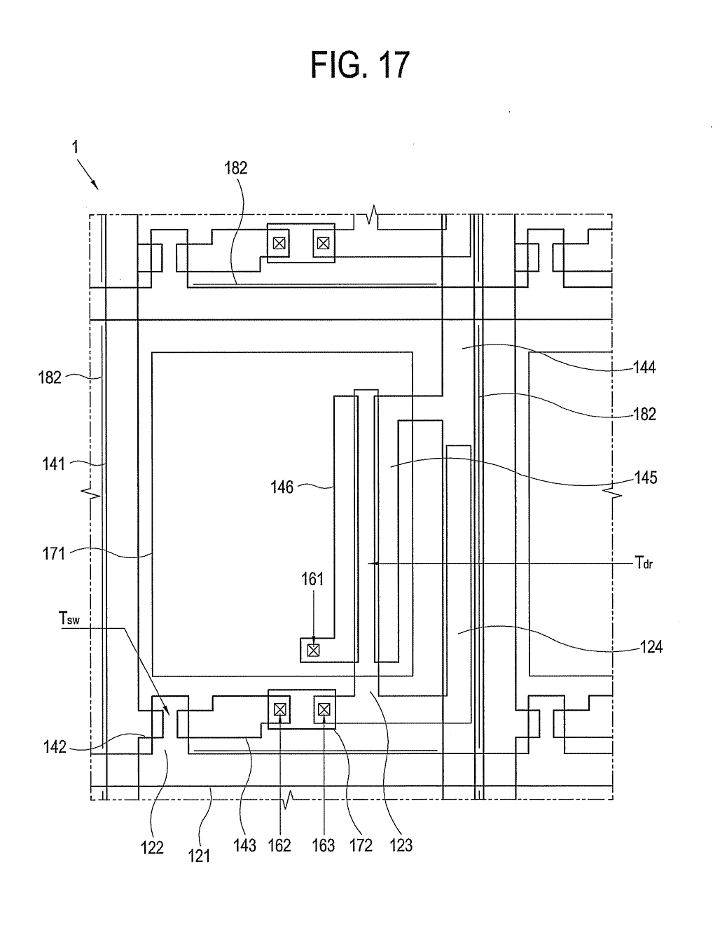

Referring to FIG. 17, a fourth exemplary embodiment of the present invention will be described below.

Similar to the first three exemplary embodiments, in the fourth exemplary embodiment a light reflective layer 196 is formed in a groove 182. Unlike the previous exemplary embodiments, the groove 182 is formed so as to not overlap with signal wirings 121, 122, 141 and 144. The light reflective layer 196 is electrically connected with the common electrode 195, and therefore may cause an electrical interference with the signal wirings 121, 122, 141 and 144 since the common voltage is applied to the light reflective layer 196 through the common electrode 195. According to the fourth exemplary embodiment, the electrical interference problem decreases because the light reflective layer 196 does not cross over the signal wirings 121, 122, 141 and 144.

Additionally, in the previous exemplary embodiments a color filter 155, a planarization layer 160 and a wall 180 are not located between the light reflective layer 196 and the signal wirings 121, 122, 141 and 144. The previous exemplary embodiments rely on the inorganic insulation layers 130 and 150 to protect against possible short-circuits. However, the danger of such a short circuit is further decreased according to the fourth exemplary embodiment.

Meanwhile, the signal wirings 121, 122, 141 and 144, which do not overlap with the groove 182, can vary depending on a formation position of the light reflective layer 196.

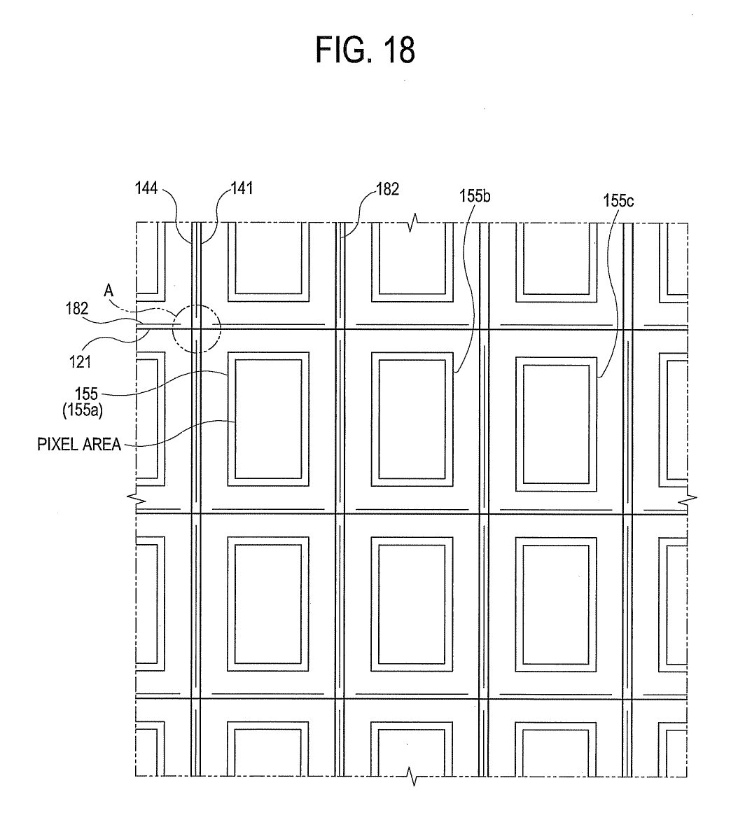

Referring to FIG. 18, a fifth exemplary embodiment of the present invention will be described below.

A groove 182 in which a light reflective layer 196 is formed to enclose a pixel area in four directions. However, in the present exemplary embodiment the reflective layer is not formed continuously.

Because the groove 182 in which a light reflective layer 196 is located in the first exemplary embodiment is formed over a planarization layer 160 and a wall 180 which are relatively thick, a slope of the groove 182 become relatively steep.

Because of the relatively steep slope of groove 182, the light reflective layer 196 may not be formed with a uniform thickness and coverage. Differences in thickness and coverage of a common electrode may lead to an uneven application of a common voltage to the common electrode 195 through the groove 182. This may present an issue when the pixels are completely surrounded by the groove 182.

According to the fifth exemplary embodiment, even if the light reflective layer 196 is not formed uniformly, the common electrode 195 can receive the common voltage stably through a portion “A” of FIG. 18 where the groove 182 is not formed.

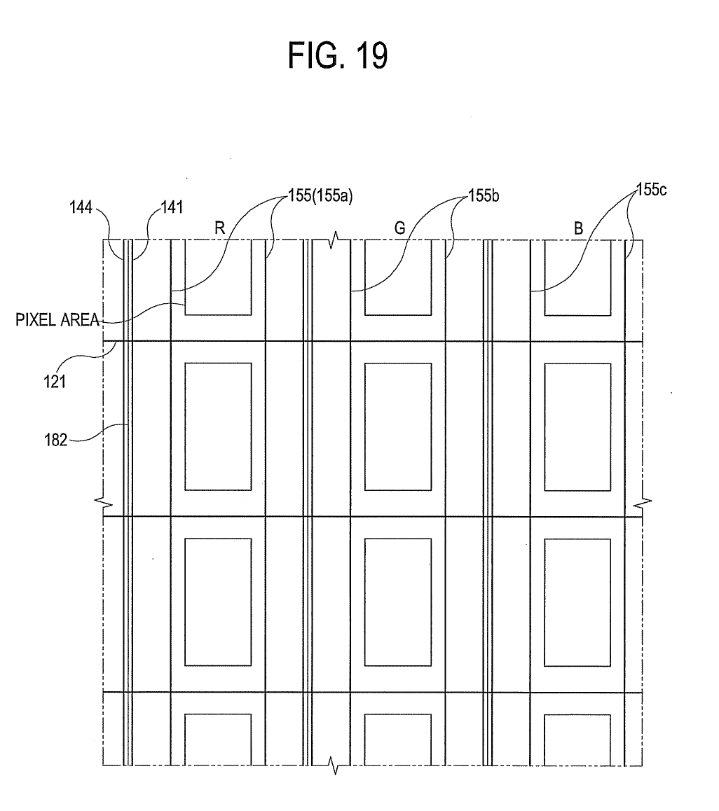

Referring to FIG. 19, a sixth exemplary embodiment of the present invention will be described below.

Respective sub-color filters 155a, 155b and 155c are formed in a stripe shape which extends along a direction of extension of a data line 141. Therefore, in the present exemplary embodiment a color of a color filter 155 changes along a direction of extension of a gate line 121, but color of the color filter 155 does not change along the a direction of extension of the data line 141.

In the present exemplary embodiment, the groove 182 in which the light reflective layer 196 is formed is formed only along the direction of extension of the data line 141.

According to the sixth exemplary embodiment, even if a mixing of light of the same color occurs due to the lack of a reflective layer between adjacent pixels of the same color, a mixing of light of different colors may be reduced or effectively prevented.

Similarly, the color filters may be arranged to extend along a direction of extension of the gate lines and the groove 182 in which the reflective layer 196 is formed may be formed to extend along a direction of extension of the gate lines.

Although several exemplary embodiments of the present invention have been shown and described, it will be appreciated by those skilled in the art that changes may be made in these exemplary embodiments without departing from the principles and spirit of the invention, the scope of which is defined in the appended claims and their equivalents.

As described above, the present invention provides a display device having an excellent light emitting efficiency.

What is claimed is:

1. A display device comprising:
an insulation substrate;
a thin film transistor disposed on the insulation substrate and which includes a drain electrode;
an insulation layer disposed on the thin film transistor and which includes a contact hole which exposes the drain electrode;
a first electrode disposed on the insulation layer and which electrically connects with the drain electrode through the contact hole;
a wall disposed on the insulation layer, the wall including
an opening and a groove, wherein the opening at least partially exposes the first electrode and the groove at least partially encloses the opening;
an organic layer disposed on the first electrode exposed through the opening in the wall; and
a second electrode disposed on the organic layer and the wall, at least a portion of the second electrode being disposed on the groove.

2. The display device according to claim 1, wherein the first electrode comprises a transparent conductive material and the second electrode comprises a reflective material.

3. The display device according to claim 2, further comprising a color filter disposed between the insulation substrate and the first electrode, and
wherein the organic layer emits white light.

4. The display device according to claim 3, wherein the insulation layer comprises a planarization layer made of an organic material, and the color filter is located between the planarization layer and the insulation substrate.

5. The display device according to claim 4, wherein the groove extends to the planarization layer, and a distance between a lower end of the groove and the insulation substrate is equal to or smaller than a distance between a lower end of the color filter and the insulation substrate.

6. The display device according to claim 4, wherein the insulation layer further comprises an inorganic insulation layer located between the planarization layer and the insulation substrate, and the color filter is located between the inorganic insulation layer and the planarization layer.

7. The display device according to claim 6, wherein the groove extends to the planarization layer, and the second electrode, which is located on the groove, contacts the inorganic insulation layer.

8. The display device according to claim 6, wherein the groove extends to the planarization layer, and a distance between a lower end of the groove and the insulation substrate is equal to or smaller than a distance between a lower end of the color filter and the insulation substrate.

9. The display device according to claim 1, wherein the groove at least partially encloses the first electrode in a substantially closed loop.

10. The display device according to claim 1, wherein the groove only partially encloses the first electrode.

11. The display device according to claim 1, further comprising a signal wiring which is disposed on the insulation substrate, wherein the groove does not cross over the signal wiring.

12. The display device according to claim 1, wherein the organic layer is separated from the groove.

13. The display device according to claim 1, wherein the organic layer extends to substantially cover the wall.

14. A display device comprising:
an insulation substrate;
a thin film transistor disposed on the insulation substrate and which includes a drain electrode;
an insulation layer disposed on the thin film transistor and which includes a contact hole which exposes the drain electrode;
a first electrode disposed on the insulation layer and which electrically connects with the drain electrode through the contact hole;
a wall disposed on the insulation layer, the wall including an opening and a groove, wherein the opening exposes the first electrode and the groove at least partially encloses the first electrode;
an organic layer disposed on at least a portion of the first electrode exposed through the opening in the wall;
a second electrode disposed on the organic layer and the wall, at least a part of the second electrode being disposed on the groove; and
a color filter disposed between the insulation substrate and the first electrode.

15. A display device comprising:
an insulation substrate;
a first electrode, an organic layer and a second electrode, sequentially disposed on the insulation substrate, the organic layer including a light emitting layer which emits white light;
a color filter located between the insulation substrate and the first electrode; and
a light reflective layer enclosing a pixel area where the first electrode and the organic layer contact,
wherein the light reflective layer is disposed at an oblique angle with respect to the first electrode and extends in a direction substantially towards the insulation substrate, thereby preventing light mixing between adjacent pixel areas.

16. The display device according to claim 15, further comprising an inorganic insulation layer disposed on the insulation substrate, wherein the color filter is located between the inorganic insulation layer and the first electrode, and the light reflective layer contacts the inorganic insulation film.

17. The display device according to claim 15, wherein the light reflective layer and the second electrode are integrated in one body.

18. The display device according to claim 15, wherein a distance between a lower end of the light reflective layer and the insulation substrate is equal to or smaller than a distance between a lower end of the color filter and the insulation substrate.

19. The display device according to claim 15, wherein the light reflective layer at least partially encloses the pixel area in a substantially closed loop.

20. The display device according to claim 15, wherein the light reflective layer only partially encloses the pixel area.

21. The display device according to claim 15, further comprising a signal wiring disposed on the insulation substrate, wherein the groove does not cross over the signal wiring.

22. The display device according to claim 15, wherein the organic layer is separated from the light reflective layer in a region where the light reflective layer extends in a direction oblique to the first electrode.

23. A method of manufacturing a display device, the method comprising:
disposing a thin film transistor on an insulation substrate, the thin film transistor including a drain electrode;
disposing an insulation layer on the thin film transistor, the insulation layer including a contact hole which exposes the drain electrode;
disposing a first electrode on the insulation layer, the first electrode electrically connecting with the drain electrode through the contact hole;
disposing a wall on the insulation layer, the wall including an opening and a groove, wherein the opening at least partially exposes the first electrode and the groove at least partially surrounds the opening;
disposing an organic layer on the first electrode which is exposed through the opening in the wall; and
disposing a second electrode on the organic layer and the wall, at least a portion of the second electrode being disposed on the groove.
